(19) United States
(12) Patent Application Publication
(10) Pub. No.: US 2012/0160295 A1
(43) Pub. Date: Jun. 28, 2012

(54) SOLAR CELL CLASSIFICATION METHOD

(75) Inventors: Lawrence A. Clevenger, Hopewell Junction, NY (US); Harold J. Hovel, YORKTOWN HEIGHTS, NY (US); Rainer Klaus Krause, Kostheim (DE); Kevin S. Petrarca, Hopewell Junction, NY (US); Gerd Pfeiffer, Hopewell Junction, NY (US); Kevin Prettyman, Hopewell Junction, NY (US); Brian C. Sapp, Hopewell Junction, NY (US)

(73) Assignee: INTERNATIONAL BUSINESS MACHINES CORPORATION, Armonk, NY (US)

(21) Appl. No.: 13/167,792

(22) Filed: Jun. 24, 2011

(30) Foreign Application Priority Data
Jun. 25, 2010 (DE) 10167293.9

(51) Int. Cl. H01L 31/042; H01L 31/18; G01R 31/10

(52) U.S. Cl. 136/244; 324/750.05; 438/15; 257/E31.11

(57) ABSTRACT

A method for characterizing the electronic properties of a solar cell to be used in a photovoltaic module comprises the steps of performing a room temperature IV curve measurement of the solar cell and classifying the solar cell based on this IV curve measurement. In order to take stress-related effects into account, the solar cells are reclassified depending on the result of an additional measurement conducted on the solar cells under stress. This stress-related measurement may be gained from light induced thermography (LIT) yielding information on diode shunt areas within the solar cell.

### BACKGROUND

The present invention relates generally to the manufacture of photovoltaic modules in which a plurality of solar cells are electrically interconnected. Specifically, the invention relates to a method for characterizing and classifying solar cells to be used in photovoltaic modules.

Photovoltaic modules for converting solar energy to electrical energy generally are made up of a set of solar cells which are mounted on a common base and are electrically interconnected. In order to minimize the mismatch which occurs whenever the IV characteristics of the solar cells within a photovoltaic module are not identical, modules are commonly built out of solar cells with similar IV characteristics.

Various methods of sorting solar cells are used by manufacturers of photovoltaic modules in an effort to minimize the cell mismatch. Generally, these methods classify the solar cells based on their IV curves so that cells with similar IV characteristics are assigned to bins with a pre-defined binning tolerance.

At present, classification of photovoltaic cells for module assembly is generally carried out based on IV measurements of the cells at room temperature. However, this has been found to be inadequate for high-performance applications and requirements. Specifically, it has been found that some cells' performance deteriorates when the cell is operating in a stressed environment, such as when the cell is exposed and heated up by sunlight. This may result in a mismatch of solar cells in a photovoltaic module at operating conditions since the cells within the module, even though they display comparable IV characteristics at room temperature, are found to exhibit different IV characteristics under thermal stress.

### BRIEF SUMMARY

According to one embodiment of the present invention, a method for characterizing electronic properties of a solar cell for use in a photovoltaic module includes performing a first IV curve measurement of the solar cell at room temperature. The method further includes classifying the solar cell based on the first IV curve measurement. The method also includes reclassifying the solar cell based on a result of an additional measurement yielding information on behavior of the solar cell under a stress.

According to another embodiment of the present invention, a method of manufacturing a photovoltaic module having a plurality of solar cells includes manufacturing the solar cells. The method includes performing IV curve measurements of the solar cells at room temperature. The method includes classifying the solar cells based on the IV curve measurements. The method further includes reclassifying the solar cells based on a result of an additional measurement yielding information on behavior of the solar cells under a stress. The method also includes assembling the photovoltaic module out of solar cells belonging to a same class.

According to another embodiment of the present invention, a photovoltaic module includes a plurality of solar cells. The solar cells are classified according to their respective IV curve characteristics into an IV class and according to a stress-related parameter into a stress class which may be the same or lower than the IV class. All solar cells within the photovoltaic module belong to the same stress class.

### BRIEF DESCRIPTION OF THE DRAWINGS

The present invention is described in the detailed description below, in reference to the accompanying drawings that depict non-limiting examples of exemplary embodiments of the present invention.

FIG. 1 shows a schematic view of a photovoltaic module with a plurality of solar cells;

FIG. 2 is a schematic perspective view of a setup for conducting light induced thermography (LIT) measurements on a solar cell;

FIG. 3a shows an LIT thermal image of a solar cell with diode shunt areas;

FIG. 3b shows an LIT thermal image of another solar cell with diode shunt areas;

FIG. 4a is a flow chart showing one embodiment of a method for classifying or “binning” solar cells to be used in a photovoltaic module;

FIG. 4b is a flow chart showing another embodiment of a method for classifying solar cells to be used in a photovoltaic module;

FIG. 5 is a flow chart showing one embodiment of a method for diode shunt area detection and integration within a solar cell; and

FIG. 6 is a flow chart showing one embodiment of a method for manufacturing the photovoltaic module shown in FIG. 1.

In the drawings, like elements are referred to with equal reference numerals. The drawings are merely schematic representations, not intended to portray specific parameters of the invention. Moreover, the drawings are intended to depict only typical embodiments of the invention and therefore should not be considered as limiting the scope of the invention.

### DETAILED DESCRIPTION

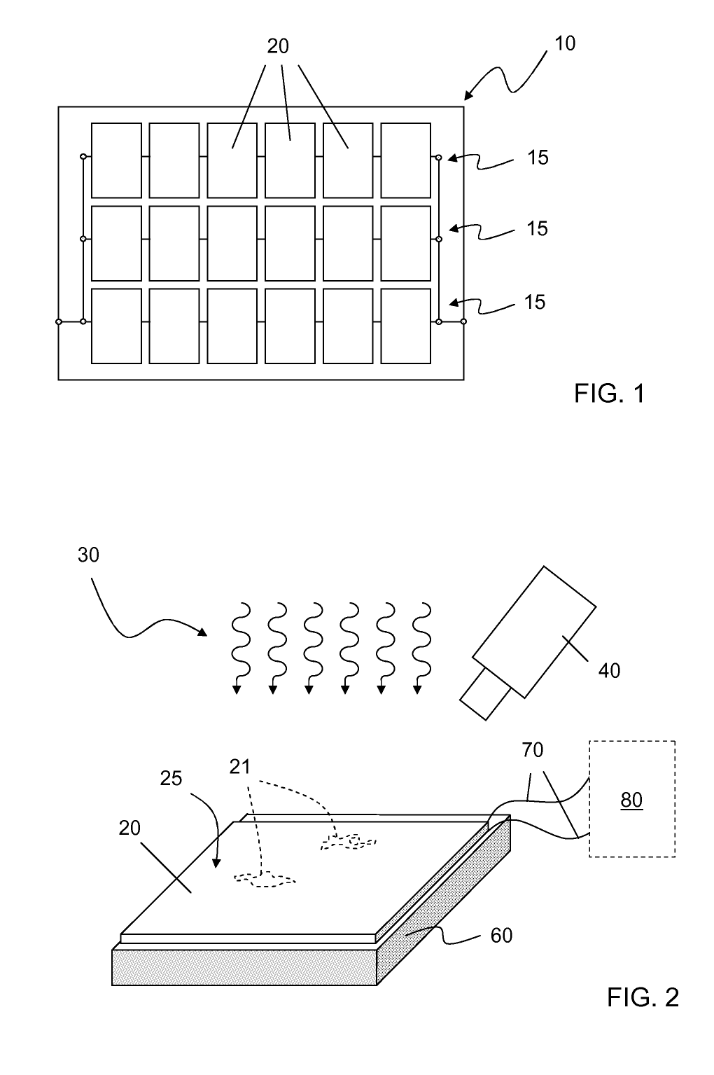

The present invention comprises an accurate and reliable classification method for solar cells which is based on IV curve measurements of the solar cells while also taking into consideration the solar cells' response to thermal stress, including a deterioration of performance at elevated temperatures. The present invention enables a reliable classification at the end of the solar cells' manufacturing process. FIG. 1 shows a schematic view of a photovoltaic module 10 containing a plurality of electrically interconnected solar cells 20. The cells 20 may be connected in series to achieve a desired output voltage and/or in parallel to provide a desired amount of current source capability. In the embodiment of FIG. 1, cells 20 are connected in series to form strings 15 which are in turn connected in parallel to form photovoltaic module 10.

If the cells 20 within module 10 differ with respect to their electrical characteristics, cells connected in series do not perform at their individual maximum power point. Instead, cells perform at a combined maximum which is less than the sum of the individual maxima. Thus, in order to optimize the performance of photovoltaic module 10, all cells 20 within this module 10 should be closely matched with respect to their essential characteristics. In order to achieve this, module manufacturers need to classify cells according to their substantial features, in a process known as “binning”, and to compile photovoltaic modules 10 out of cells 20 which all belong to the same or a similar class or “bin”.

FIG. 6 is a flow chart showing one embodiment of a method 200 for manufacturing a photovoltaic module 10 from a set of solar cells 20 with well-matched properties, such as belonging to the same class or “bin”. Method 200 begins with step 105 of manufacturing the solar cells 20.

As is well known in the art, a solar cell's behavior under stress is strongly influenced by the presence of so-called diode shunt areas 21 (as shown in FIG. 2) which are regions within the solar cell 20 in which higher rates of recombination occur. This increased recombination rate may be due to a complex formed between oxygen and boron impurities contained in the silicon base material of the photovoltaic cells. These impurities form scattering centers which reduce carrier lifetime. Efforts have been made to improve the base material for solar cells by controlling and/or specifying oxygen levels during silicon wafer manufacture. Irrespective of these efforts, the oxygen content of the silicon wafer has to be determined in order to accurately predict recombination rates due to these oxygen-boron complexes. Thus, manufacturing step 105 may comprise a measurement of the oxygen concentration within a silicon ingot or a silicon level can be measured, such as by using Fourier transform infrared spectroscopy (FTIR). Alternatively, the oxygen concentration of the silicon ingot or wafer may be obtained by modeling. Subsequently, the silicon wafers are classified or “binned” according to specific ranges of oxygen content, as defined by the manufacturer of photovoltaic cells. These binned wafers can then be used to manufacture solar cells 20 with a well-defined quality level.

Once solar cells 20 have been produced, preferably from wafers of well-defined oxygen content, in step 105, the solar cells 20 need to be characterized and classified according to their electronic properties in steps 110, 120 and 160 before they are combined with other solar cells with similar IV behavior to be integrated into photovoltaic module 10 (step 190 of method 200).

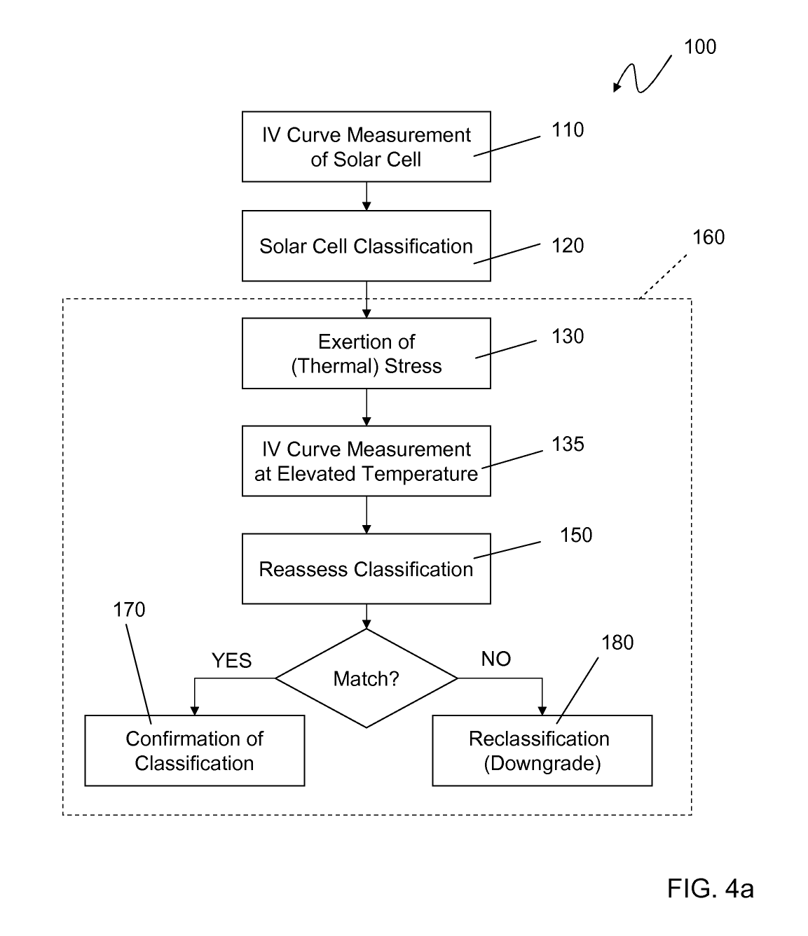

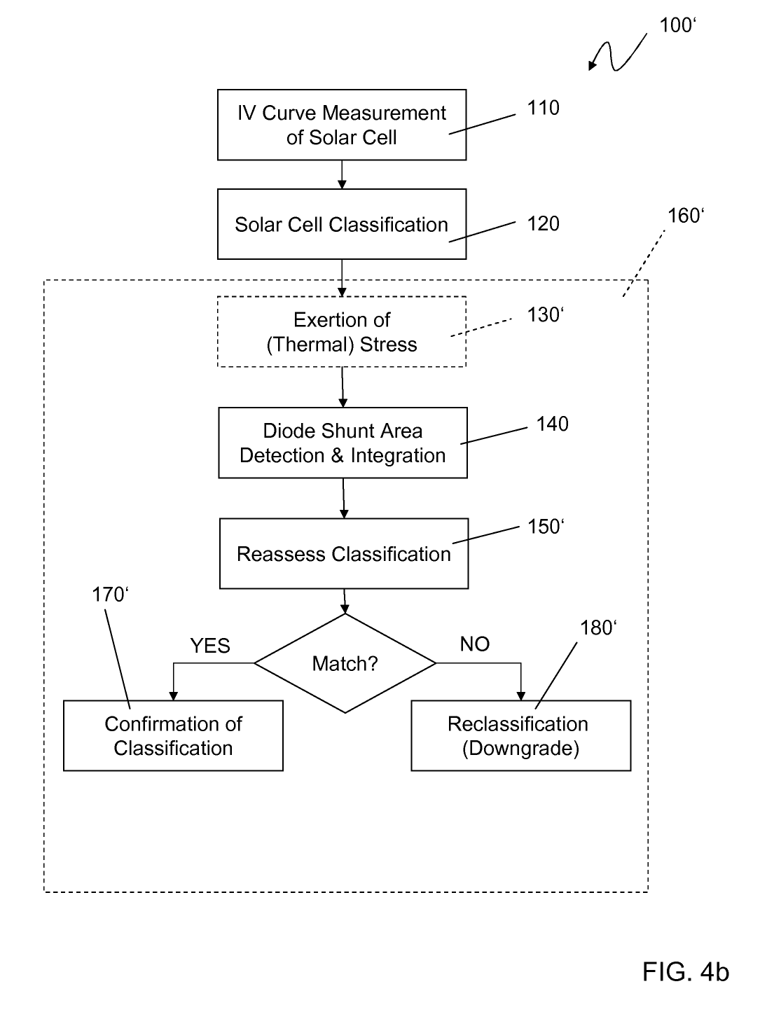

FIG. 4a is a flow chart showing one embodiment of a method 100 for classifying or “binning” solar cells 20 to be used in a photovoltaic module 10. In a first step 110, IV curve measurements are carried out on each of the solar cells 20 to be used in photovoltaic module 10. The solar cell 20 is exposed to a short light flash of several milliseconds duration. A response is assessed by measuring the solar cell's 20 IV characteristics. Depending on the results of these measurements, the cell 20 is assigned to a class or “bin” in step 120.

The assessment of solar cells 20 in step 110 is typically carried out at room temperature conditions, whereas actual operation of the solar cells 20 may take place at elevated temperatures. Incident sunlight, heat and the like may induce thermal and mechanical stresses in the solar cells 20 which, in turn, may impact cell performance. While the solar cell 20 is exposed to a flash of light in step 110, this exerts a thermal stress which is much less than the one normally exerted to sunlight exposure. Moreover, the characterization using a single flash of light captures only room temperature parameters while realistic operating temperatures may be 20° C. or 30° C. higher. Also, the cell behavior during the cold months and during summer may be somewhat different due to very different operating temperatures.

Thus, while IV characteristic obtained for the unstressed solar cell 20 can be used as a basis for a first classification or “binning” of the cells in step 120, stress induced changes of the characteristics must be taken into account in order to obtain an accurate assessment of future cell performance under operating conditions. Thus, additional measurements on the solar cell 20 and reclassification are carried out in step 160 in which the effects of a well-defined stress on solar cell 20 are studied and estimated.

A simple experimental way of assessing thermal effects within the solar cell 20 (step 160) consists in heating the cell 20 to a temperature of about 40° C. to 80° C. (step 130) and performing IV curve measurements at this elevated temperature (step 135). An exemplary experimental setup for carrying out this procedure is shown in FIG. 2. Solar cell 20 can be attached to a hot plate 60 heated to a desired temperature. IV curve measurements can be carried out by connecting electrical contacts 70 of solar cell 20 to IV measurement equipment 80. This yields an indication of how the solar cell 20 will perform under typical operating conditions. If IV characteristics of a specific cell 20 at these elevated temperatures display strong deviations from “normal” behavior, this will lead to a reclassification of the cell 20 (step 150 of method 100, see FIG. 4a), so that this specific cell 20 will be assigned to a different “bin” (step 180) and thus be grouped with other cells displaying similar properties.

FIG. 4b shows an alternative preferred embodiment of a method 100′ for characterizing solar cells 20 to be used in photovoltaic modules 10. As in the method 100 of FIG. 4a, a preliminary classification of the solar cells 20 is carried out based on room temperature IV curve measurements (steps 110 and 120). In the subsequent reclassification step 160′, the prospective reaction of solar cell 20 to thermal stress is determined from an estimation of the number and spatial extent of diode shunt areas 21 within solar cell 20 (step 140). As described above, diode shunt areas 21 are defined as regions within the solar cell 20 in which recombination rates are increased. Thus, the amount or size of diode shunt areas 21 is indicative of how the respective solar cell 20 will react under thermal stress.

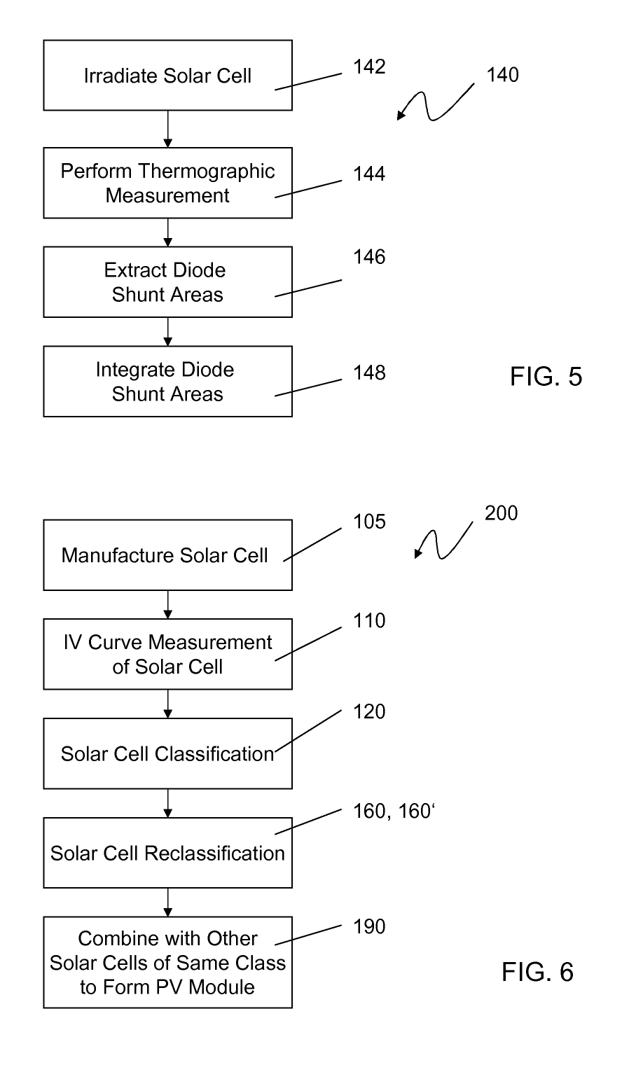

In assessing the sizes and/or shapes of diode shunt areas 21, it has been found that thermal imaging, in particular light induced thermography (LIT), is an especially suitable method for detecting and visualizing diode shunt areas 21 within solar cell 20. FIG. 2 shows a schematic perspective view of an experimental setup for conducting thermal imaging measurements on solar cell 20. FIG. 5 is a flow chart showing one embodiment of a method 140 for diode shunt area detection and integration within a solar cell. Solar cell 20 is illuminated by a light pulse 30 of electromagnetic radiation, such as visible and/or infrared spectrum, in step 142. The cell's thermal response is recorded using a thermally sensitive digital camera such as an IR camera 40 yielding 2D images of the temperature distribution on the surface 25 of solar cell 20 (step 144). When illuminated by light pulse 30, diode shunt areas 21, due to their higher recombination rates, experience heating due to an increase of current. Therefore, diode shunt areas 21 may be detected directly from the 2D images furnished by IR camera 40. If the integrated surface of the diode shunt areas exceeds a predetermined clip level, for example, 10% of the total surface in a non-limiting example, the measured cell is downgraded to the next lower bin, or even further.

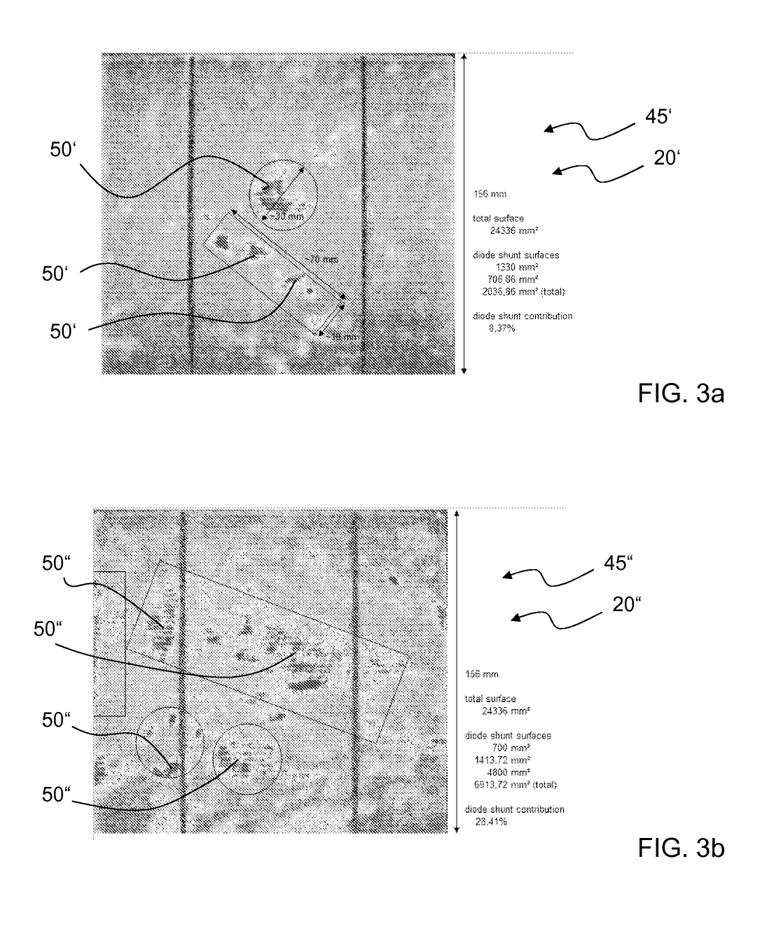

FIGS. 3a and 3b show examples of spatially resolved thermal images 45′, 45″ of two solar cells 20′, 20″. Thermal image 45′ of FIG. 3a is seen to contain a few patches 50′ of elevated temperature indicative of diode shunt areas of the corresponding solar cell 20′. In thermal image 45′, all regions displaying a temperature above a pre-defined threshold can be classified as belonging to diode shunt areas (step 146). These thermal image data 45′ can be evaluated using standard image analysis techniques. In particular, the areas of these regions 50′ may be approximated or fitted by geometric shapes, as indicated by the circle and the rectangle in FIG. 3a, and summed up to yield a parameter directly related to the total diode shunt area of solar cell 20′ (step 148). Alternatively, the areas of all pixels recording a temperature above the threshold may be added up to yield a more accurate estimate of the image of the total diode shunt area of solar cell 20′. The extent of regions with elevated recombination rates within the solar cell are calculated.

Thermal image 45″ of FIG. 3b is seen to contain considerably more high temperature patches 50″ than thermal image 45′ of FIG. 3a, which indicates that total diode shunt area of solar cell 20″ is much larger than total diode shunt area of solar cell 20′. Assuming that solar cells 20′ and 20″ were classified in step 120 to belong to the same bin, results of thermal measurements (i.e. thermal images 45′, 45″ of FIG. 3a, 3b) show that solar cells 20′, 20″ will behave differently under stress and thus should be reclassified to different bins. This is implemented in step 150′ of method 100′ (see FIG. 4b). If total diode shunt area of a solar cell 20 exceeds a pre-defined threshold, such as 10% of the solar cell's total surface 25 in a non-limiting example, this solar cell 20 will be reclassified, and assigned to a different (“lower”) bin (step 180). This reflects the fact that solar cells with large diode shunt areas, cells with larger areas of increased recombination, are expected to degrade faster, limiting the power output of an entire string 15 of solar cells 20 connected in series within a photovoltaic module 10.

In the case of solar cell 20′, the integrated area of the high-temperature patches 50′ of image 45′ amounts to approximately 8% of the cell's total surface 25′ and thus is lower than the pre-defined threshold value of 10% in this non-limiting example. Therefore, the original classification of solar cell 20′ is confirmed (step 170′), such that solar cell 20′ remains in its original bin as assigned in step 120. On the other hand, the integrated high-temperature patches of image 45″ of solar cell 20″ (as extracted from FIG. 3b) amount to approximately 28% of the cell's total surface 25″ and thus exceed the pre-defined threshold of 25% in this non-limiting example. Therefore, solar cell 20″ is reassigned to a bin of solar cells with “inferior” IV curve characteristics, thus reflecting the fact that cell 20″, while it has “superior” room temperature IV characteristics, will “weaken” under stress. As a consequence, during compilation of photovoltaic modules 10, solar cells 20′, 20″ will be integrated into different photovoltaic modules.

As described, analysis of thermal images 45′, 45″ enables a more accurate classification according to the cell efficiency at the end of the solar cell manufacturing process which will result in an improved cell matching at the module level. Preferably, thermal imaging measurements as shown in FIG. 2 are made using forward as well as reverse bias configurations of the solar cell 20. This will highlight the diode shunt areas.

Solar cells 20 not only contain diode shunt areas, but generally also comprise other shunt mechanisms such as ohmic shunts. However, these other shunt mechanisms are less temperature dependent than diode shunts and are therefore not as strongly affected by typical operational conditions. While diode-like shunts display an exponential temperature dependence and, as a consequence, severely degrade solar cell efficiency at elevated operating temperatures, the relative contribution of ohmic shunts decreases at elevated temperatures.

The detection of diode shunt areas (step 140) based on thermal imaging may be carried out at ambient (room temperature) conditions. In addition or alternatively to room temperature measurement, these stress simulation measurements may be carried out at elevated temperatures (step 130′) in order to obtain an indication of how the solar cell will perform under typical operating conditions. The solar cell's performance at elevated temperature can be simulated by placing the solar cell 20 on a hot plate 60 while it is exposed to light flash 30 and while diode shunts and IV curves are measured. This constitutes a way of applying direct thermal stress to the solar cell 20 during testing. The elevated temperature causes an increase of diode shunt areas which are measured using the thermal imaging technique. The hot plate 60 temperature is preferably chosen in the range between 40° C. and 80° C. which is sufficient to simulate typical thermal operation conditions during mid-day sunlight exposure.

Methods 100, 100′ described above comprise a re-evaluation of the prospective performance of a solar cell 20 after the regular IV curve measurements at room temperature (step 110) have been carried out and used for classification (step 120). Methods 100, 100′ thus hold a potential of improving cell matching, especially at typical operating temperatures. If a batch of solar cells 20 to be used in a photovoltaic module 10 is characterized using method 100 or method 100′, solar cells 20″ with large diode shunt areas will be downgraded and will thus not be combined with solar cells 20′ containing few diode shunt areas, thus securing a higher reliability of the individual cells in a serial string 15 within photovoltaic module 10.

The corresponding method 200 of manufacturing a photovoltaic module 10 is displayed schematically in the flow diagram of FIG. 6. Solar cells 20 to be used in photovoltaic module 10 are manufactured (step 105) and classified (“binned”) in step 120 based on IV curve measurements. Each solar cell 20 is thus assigned to a so-called “IV class”. Subsequently, the solar cells 20 are subjected to a measurement which yields a stress based characterization of the finished solar cell 20. In it, the binning of step 120 is reassessed based on the solar cells' 20 reaction to stress (step 160). This stress may consist in exposing the solar cells 20 to a flash of light 30 and/or to an elevation in temperature. If, during reassessment step 160, a given solar cell 20″ exhibits signs of defects or of deterioration above a pre-defined threshold, such as a large diode shunt area which may be detected by thermal imaging, this cell 20″ will be downgraded to a so-called “stress class” which is lower than the “IV class” originally assigned in step 120. If, on the other hand, a given solar cell 20′ proves to be stress-resistant, this solar cell 20′ retains in its original classification, so that the “stress class” of this solar cell 20′ is identical to its “IV class”.

After reassessment step 160, any given “stress class” bin thus contains solar cells 20′ whose “stress class” is identical to their “IV class” and solar cells 20″ whose “stress class” is lower than their “IV class” (i.e. which were downgraded as a consequence of the reassessment step 160).

Finally, photovoltaic module 10 is assembled from solar cells 20 which were all classified or reclassified into the same “stress class” bin, thus assuring a good match of solar cells 20 within photovoltaic module 10. Method 200 thus enables improved cell matching based on the cell's stress performance and related stress areas, such as diode-like shunts, which may act as additional recombination areas. This ensures that the solar cells within the module will be well matched under operating conditions in which the solar cells are subject to thermal stress.

The operational test environment could also be located outdoors. In this case, cell testing is performed in sunlight and real operational conditions, thus simulating an actual module operating environment.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method for characterizing electronic properties of a solar cell for use in a photovoltaic module, comprising:
performing a first IV curve measurement of the solar cell at room temperature;
classifying the solar cell based on the first IV curve measurement; and
reclassifying the solar cell based on a result of an additional measurement yielding information on behavior of the solar cell under a stress.

2. The method according to claim 1, wherein the reclassifying step comprises exerting a thermal stress on the solar cell and performing a second IV curve measurement of the thermally stressed solar cell.

3. The method according to claim 2, wherein the exerting a thermal stress step comprises heating the solar cell with a hot plate.

4. The method according to claim 1, wherein the reclassifying step comprises performing an assessment of diode shunt areas within the solar cell.

5. The method according to claim 4, wherein the performing an assessment of diode shunt areas step comprises:
irradiating the solar cell with a light pulse;
performing a thermal imaging measurement of a surface of the solar cell;
detecting diode shunt areas within the solar cell; and
integrating all diode shunt areas.

6. The method according to claim 4, wherein a classification of the solar cell is downgraded if a sum of all diode shunt areas within the solar cell exceeds a pre-defined threshold.

7. The method according to claim 4, wherein the performing an assessment of diode shunt areas step is performed at room temperature.

8. The method according to claim 4, wherein the performing an assessment of diode shunt areas step is performed at an elevated temperature between 40° C. and 80° C.

9. The method according to claim 5, wherein the performing a thermal imaging measurement step is performed in forward and reverse bias configurations of the solar cell.

10. A method of manufacturing a photovoltaic module having a plurality of solar cells, comprising:
manufacturing the solar cells;
performing IV curve measurements of the solar cells at room temperature;
classifying the solar cells based on the IV curve measurements;
reclassifying the solar cells based on a result of an additional measurement yielding information on behavior of the solar cells under a stress; and
assembling the photovoltaic module out of solar cells belonging to a same class.

11. A photovoltaic module comprising a plurality of solar cells, wherein the solar cells are classified according to their respective IV curve characteristics into an IV class and according to a stress-related parameter into a stress class which may be the same or lower than the IV class, and wherein all solar cells within the photovoltaic module belong to the same stress class.
